(19) United States
(12) Patent Application Publication
(10) Pub. No.: US 2008/0064346 A1
(43) Pub. Date: Mar. 13, 2008

(54) METHOD FOR CONNECTING A CONTACTLESS INTEGRATED CIRCUIT TO A NFC COMPONENT

(75) Inventor: Bruno CHARRAT, Aix En Provence (FR)

Correspondence Address: PANITCH SCHWARZE BELISARIO & NADEL LLP, ONE COMMERCE SQUARE, 2005 MARKET STREET, SUITE 2200, PHILADELPHIA, PA, 19103, US

(73) Assignee: INSIDE CONTACTLESS, Aix En Provence (FR)

(21) Appl. No.: 11/853,257

(22) Filed: Sep. 11, 2007

(30) Foreign Application Priority Data
Sep. 11, 2006 (FR) 06 07929

(51) Int. Cl. H03D 7/16

(52) U.S. Cl. 455/131

(57) ABSTRACT

A method for exchanging data with an integrated circuit includes antenna connection terminals. The method includes not connecting the antenna connection terminals of the integrated circuit to an antenna, applying an alternating emulation signal at least to a first antenna connection terminal of the integrated circuit, by way of a wire link, in order to emulate the presence of an antenna signal on the first antenna connection terminal, sending data to the integrated circuit by injecting them in the emulation signal, and receiving data sent by the integrated circuit by taking them from the emulation signal.

### BACKGROUND OF THE INVENTION

Embodiments of the present invention are related to the development and improving of the NFC technology (Near Field Communication).

The NFC technology is currently developed by an industry consortium under the name of NFC Forum (http://www.nfc-forum.org). The NFC technology derives from Radio Frequency Identification technology (RFID) and uses NFC components having a contactless communication interface (contactless data sending/receiving) and several operating modes, i.e., a “reader” mode, a “card emulation” mode, and a “device” mode (or “device-to-device”). In the reader mode, the NFC component operates as a conventional RFID reader to read or write access to a RFID chip (chip card or contactless tag in particular). It emits a magnetic field, sends data by modulating the amplitude of the magnetic field and receives data sent by retromodulation (charge modulation). In the emulation mode, described by European Patent No. EP 1 327 222 in the name of the applicant, the NFC component operates in a passive way, as a transponder, to dialog with a reader or a NFC component in the active mode, and to be seen by the other reader or NFC component as a RFID chip. The NFC component in the passive mode does not emit any magnetic field, it receives data by demodulating a magnetic field emitted by the other reader and sends data by retromodulation.

In the device mode, the component must match another NFC component and each NFC component alternately puts itself in a passive state (without field emission) to receive data and in an active state (with field emission) to send data.

In addition to the three operating modes, a NFC component can implement several contactless communication protocols and is for example able to exchange data according to these various protocols, for example ISO 14443-A and ISO 14443-B which will be hereinafter designated “ISO-A” and “ISO-B”, respectively. Each protocol defines an emission frequency of the magnetic field, a method for modulating the amplitude of the magnetic field to send data in the active mode, and a retromodulation method for sending data in the passive mode. A NFC component is thus a multimode and multiprotocol device. The applicant for example sells a NFC component under the designation “MicroRead”.

Because of its wide communication capabilities, a NFC component is intended to be integrated in portable devices like mobile phones or a Personal Digital Assistant (PDA). That leads to implement a NFC chipset of the type shown in FIG. 1, referenced CSET, i.e., a set of chips comprising a NFC component referenced NFCM and at least one host processor HP1. In numerous applications, the NFC chipset also comprises a second host processor HP2, as shown, and sometimes a third or even more. A host processor is usually a microprocessor or a microcontroller which is connected to a port of the NFC component.

The host processor HP1 is for example a secure integrated circuit, like an integrated circuit of a “Subscriber Identity Module” card (SIM), and the host processor HP2 is for example a non-secure processor like the baseband circuit of a mobile phone (or radiotelephony circuit). The resources of the NFC component are put at the disposal of the processors HP1, HP2 to enable them to manage contactless applications. These applications are shown in FIG. 2, which represents a mobile phone 30 equipped with the NFC chipset of FIG. 1, comprising the NFC component and the host processors HP1, HP2. This figure shows applications of AP1, AP2 and AP3 type. In the applications of AP1 type, the NFC-type component is in the reader mode to read or write a contactless integrated circuit CLCT, for example an electronic business card or an advertising tag. The mobile phone is in this case used as a RFID reader. In the applications of AP2 type, the NFC component of the phone 30 is in the card emulation mode to be read by conventional readers RD. These applications usually are payment applications or not free access control applications (payment machine, metro entrance, etc.). The mobile phone 30 is then used as a chip card. In the applications of AP3 type, the NFC component of the phone 30 is in the device mode and dialogs with another device, for example another NFC component integrated in a mobile phone 31 or in a computer 32.

AP1 and AP3 type applications are usually managed by the non-secure processor HP2, whereas the AP2 type applications are most often managed by the secure processor HP1, as shown in FIG. 1, because the access to the service requires a secure identification of the subscriber. Free and non-secure applications of AP2 type can also be managed by the processor HP2, for example reading data of “details” type (addresses and phone numbers) in the phone, etc.

Thus, the implementation of a NFC chipset requires to provide conveying data flows between the NFC component and each host processor HP1, HP2. The data flows comprise incoming data, received by the NFC component by means of its contactless communication interface and conveyed to the host processors, and outgoing data, sent by the host processors and conveyed to the NFC component for it to send them by means of its contactless communication interface.

Creating a data path between a NFC component and a host processor HP2 of baseband type usually does not raise any technical problem because the host processor, integrated into the mobile phone, has wide communication means, for example a “Universal Asynchronous Receiving Transmitting” (UART) communication port allowing data to be transferred at high rate.

Creating a data path between a NFC component and a secure integrated circuit IC as host processor HP1 is shown in FIG. 3, which schematically shows the architecture of the component NFCM of FIG. 1 and its connection with the integrated circuit IC.

The component NFCM comprises a contactless interface circuit CLINT, an antenna circuit ACT connected to the circuit CLINT, an alternating signal generator FGEN, a main controller NFCC (microprocessor or microcontroller) and an interface circuit INT1 allowing the integrated circuit IC to be connected. The interface circuit CLINT and the antenna circuit ACT form the contactless communication interface of the component NFCM and the antenna circuit ACT comprises an antenna coil Lr. The generator FGEN supplies an alternating signal S1 (Fc) of frequency Fc, used as triggering signal of the antenna circuit ACT allowing a magnetic field FLD1 (Fc) to be emitted when the component NFCM is in the active mode. The generator FGEN is stopped in the passive mode, the component NFCM receiving in this case a magnetic field FLD2 (Fc) emitted by an external device (RFID reader or other NFC component).

Determining a “universal” communication protocol between the component NFCM and the integrated circuit IC does not seem possible in practice as it faces a problem of rationalization of the industrial production of integrated circuits. Indeed secure integrated circuits are currently of two types: contact integrated circuits, usually of ISO 7816 type (SIM cards) and contactless integrated circuits, manufactured for example according to the ISO-A (ISO 14443-A) or ISO-B (ISO 14443-B) standards. There are also hybrid integrated circuits comprising both an interface ISO 7816 and a contactless communication interface.

It is important to provide integrated circuits that can be used in a conventional way but that can also be inserted in a NFC chipset, so as not to create a diversity of models of integrated circuits that would affect their cost price.

Thus, as shown in FIG. 4A, the ISO 7816 integrated circuits (IC1) are connected to the component NFCM by using their ISO 7816 contact pads, i.e., VCC, GND, IO, RST, CLK (power supply, ground, data input/output, reset and clock), which were initially designed to exchange data with a card reader via a ISO 7816 bus. Their connection to the component NFCM is made by the interface circuit INT1 which is configured to perform the management of the ISO 7816 bus and the conversion of incoming and outgoing data conveyed by the bus.

The ISO 7816 bus however has the drawback of being slow and little adapted to high rate transfers of the data received by the component NFCM by means of its contactless communication interface.

On another hand, the contactless integrated circuits have a contactless communication interface able to send and receive data with a higher rate than with the bus ISO 7816, as well as means of processing data adapted to that rate. But, this communication interface is provided to operate using an antenna circuit and in presence of a triggering magnetic field. A specific communication bus has therefore been proposed, called bus S2C, to connect this type of integrated circuit to a NFC component.

The basic principles of the bus S2C are described in the document entitled “S2C Interface for NFC, Adding a general purpose interface between NFC and Secure IC to Secure NFC, 21-01-2005, Survey V1.00” (http://www.semiconductors.philips.com/acrobat/other/identification/S2C_survey_{—}10.pdf). The bus S2C consists of a signal SIGIN sent by the integrated circuit and a signal SIGOUT sent by the NFC component. The signal SIGIN carries the envelope of a data carrier retromodulation signal that the component NFCM must apply to its antenna circuit. The signal SIGOUT is an oscillating signal which has a “Phase Shift Keying” (PSK) modulation representative of the variations of amplitude of the magnetic field received by the component NFCM in the passive mode and consequently representative of the data received by the latter.

Thus, as illustrated in FIG. 4B, the contactless integrated circuits (IC2) are connected to the component NFCM by means of dedicated contacts SIGIN, SIGOUT, the interface circuit INT1 being configured to perform the conversion of incoming and outgoing data conveyed by the bus S2C.

The bus S2C however has various drawbacks. On the one hand, it requires an adaptation of existing contactless integrated circuits by adding an interface circuit S2C. The manufacturers must therefore manufacture on the one hand batches of integrated circuits intended for contactless applications and on the other hand batches of modified integrated circuits equipped with an interface S2C. In addition, the interface S2C components, on either side of the bus S2C, switch at high rate and have a high electrical consumption. Eventually, the bus S2C does not enable energy to be transferred. Thus, if the integrated circuit is purely passive, an additional link Vcc and GND must be provided to supply it a supply voltage Vcc and the corresponding ground GND, as shown in FIG. 4B.

### BRIEF SUMMARY OF THE INVENTION

More particularly, embodiments of the present invention are directed to a device for exchanging data with a contactless integrated circuit, minimizing the modifications to be made to the integrated circuit, in order to rationalize the production of integrated circuits.

The idea of the present invention is to use the antenna connection terminals of a contactless integrated circuit to establish a data path between the integrated circuit and a NFC component. To that end, an alternating signal which emulates an antenna signal is applied at least to one antenna terminal of the integrated circuit. The emulation signal is “seen” by the integrated circuit as an antenna signal. Demodulation and modulation circuits of the integrated circuit, initially provided to act on the antenna signal, are then operational and can act on the emulation signal as if it was an antenna signal. Data can thus be sent to the integrated circuit by injecting them in the emulation signal. Data can likewise be received from the integrated circuit by extracting them from the emulation signal. In these conditions, any type of contactless integrated circuit can be used without modification, insofar as the emulation signal and the way data are injected in it or extracted from it comply with the integrated circuit. Embodiments of the present invention are therefore of nearly universal application and does not require, in principle, any modification of a contactless circuit to be applicable.

More particularly, embodiments of the present invention provide a method for exchanging data with an integrated circuit, wherein the integrated circuit comprises antenna connection terminals and means for receiving and sending data from an antenna signal received on the antenna connection terminals, and comprising not connecting the antenna connection terminals of the integrated circuit to an antenna, applying an alternating emulation signal at least to one first antenna connection terminal of the integrated circuit, by means of a wire link, in order to emulate the presence of an antenna signal on the first antenna connection terminal, sending data to the integrated circuit by injecting them in the emulation signal, and receiving data sent by the integrated circuit by taking them from the emulation signal.

According to one embodiment, injecting data in the emulation signal comprises modulating the emulation signal by means of a data carrier signal.

According to one embodiment, the data present in the data carrier signal are obtained by demodulating an antenna signal received through an antenna circuit of a component hosting the integrated circuit.

According to one embodiment, taking data from the emulation signal comprises extracting a data carrier retromodulation signal by detecting current or voltage variations in the emulation signal.

According to one embodiment, the method comprises applying a direct voltage to one second antenna connection terminal of the integrated circuit, to electrically power the integrated circuit.

According to one embodiment, the method comprises linking a ground terminal of the integrated circuit to a ground terminal of a device used to exchange data with the integrated circuit.

Embodiments of the present invention also relate to a method establishing a data path between a host integrated circuit and a NFC component comprising an antenna circuit for receiving and sending contactless data, wherein the host integrated circuit comprises antenna connection terminals and means to receive and send data by demodulating an antenna signal received on the antenna connection terminals, and comprising not connecting the antenna connection terminals of the host integrated circuit to an antenna, linking at least one first antenna connection terminal of the host integrated circuit to the NFC component by means of a wire link, applying an alternating emulation signal supplied by the NFC component at least to the first antenna connection terminal, in order to emulate the presence of an antenna signal, injecting data supplied by the NFC component in the emulation signal, and taking from the emulation signal data sent by the host integrated circuit and supplying them to the NFC component.

According to one embodiment, injecting data in the emulation signal comprises modulating the emulation signal by means of a data carrier signal.

According to one embodiment, the method comprises producing the data carrier signal by demodulating an antenna signal received in the antenna circuit of the NFC component so that the data received by the NFC component are sent to the host integrated circuit in a transparent way.

According to one embodiment, injecting data in the emulation signal comprises demodulating an antenna signal received in the antenna circuit of the NFC component to produce a first data carrier signal, decoding the first data carrier signal, rebuilding a second data carrier signal from data present in the first data carrier signal, and modulating the emulation signal, by means of a second data carrier signal.

According to one embodiment, the second data carrier signal has an encryption different from an encryption of the first data carrier signal.

According to one embodiment, taking data from the emulation signal comprises extracting a data carrier retromodulation signal, by detecting current or voltage variations in the emulation signal.

According to one embodiment, the method comprises applying the retromodulation signal to a modulation circuit of the NFC component, so that the NFC component resends the data via the antenna circuit in a transparent way.

According to one embodiment, taking data from the emulation signal comprises extracting a first data carrier retromodulation signal from the emulation signal, decoding the first retromodulation signal, rebuilding a second retromodulation signal from data present in the first retromodulation signal, and applying the second retromodulation signal to a modulation circuit to send data via the antenna circuit of the NFC component.

According to one embodiment, the second retromodulation signal has an encryption different from an encryption of the first outgoing data carrier signal.

According to one embodiment, the emulation signal oscillates at the same frequency as a working frequency of the antenna circuit of the NFC component.

According to one embodiment, the emulation signal oscillates at a frequency different from a working frequency of the antenna circuit of the NFC component.

According to one embodiment, the method comprises extracting an alternating signal of the antenna circuit, and using the alternating signal as emulation signal.

According to one embodiment, the method comprises configuring the NFC component so that it comprises an active operating mode where the NFC component applies a triggering signal to the antenna circuit and a passive operating mode where the NFC component extracts the alternating signal from the antenna circuit.

According to one embodiment, the method comprises linking one second antenna connection terminal to the NFC component by means of a wire link, and applying a direct voltage to the second antenna connection terminal, to electrically power the host integrated circuit.

According to one embodiment, the method comprises linking a ground terminal of the host integrated circuit to a ground terminal of the NFC component.

Embodiments of the present invention also relate to a NFC component comprising an antenna circuit for receiving and sending contactless data, and provided for receiving at least one host integrated circuit in order to exchange data with the host integrated circuit, comprising at least one connection terminal to connect an antenna connection terminal of a host integrated circuit of contactless operation type but without antenna, and an interface circuit to apply an alternating emulation signal to the antenna connection terminal of the host integrated circuit, in order to emulate the presence of an antenna signal, inject data supplied by the NFC component in the emulation signal, and take data sent by the host integrated circuit from the emulation signal.

According to one embodiment, the interface circuit is arranged for injecting data in the emulation signal by modulating the emulation signal by means of a data carrier signal.

According to one embodiment, the NFC component a demodulator to demodulate an antenna signal received in the antenna circuit and the data carrier signal is supplied to the interface circuit without processing so that the data received via the antenna circuit are sent to the host integrated circuit in a transparent way.

According to one embodiment, the NFC component comprises a demodulator to demodulate an antenna signal received in the antenna circuit and supply a first data carrier signal to the interface circuit, first processing means to rebuild a second data carrier signal from data present in the first data carrier signal, and a modulation circuit to modulate the emulation signal by means of the second data carrier signal.

According to one embodiment, the first processing means rebuild the second data carrier signal with an encryption different of an encryption of the first data carrier signal.

According to one embodiment, the first processing means comprise a main controller of the NFC component.

According to one embodiment, the first processing means comprise a dedicated modulation circuit of the interface circuit, different from a main controller of the NFC component.

According to one embodiment, the interface circuit comprises a detection circuit to detect current or voltage variations in the emulation signal and extract from the emulation signal a data carrier retromodulation signal.

According to one embodiment, the NFC component comprises a modulation circuit to send data via the antenna circuit, and the retromodulation signal is applied to the modulation circuit without processing so that the NFC component resends data via the antenna circuit in a transparent way.

According to one embodiment, the NFC component comprises second processing means to rebuild a second retromodulation signal from data present in the first retromodulation signal, and a modulation circuit to apply the second retromodulation signal to the antenna circuit and send data via the antenna circuit of the NFC component.

According to one embodiment, the second processing means rebuild the second data carrier signal with an encryption different of an encryption of the first data carrier signal.

According to one embodiment, the second processing means comprise a main controller of the NFC component.

According to one embodiment, the second processing means comprise a dedicated demodulation circuit of the interface circuit, different from a main controller of the NFC component, to extract the data present in the first retromodulation signal.

According to one embodiment, the emulation signal oscillates at the same frequency as a working frequency of the antenna circuit of the NFC component.

According to one embodiment, the emulation signal oscillates at a frequency different from a working frequency of the antenna circuit of the NFC component.

According to one embodiment, the NFC component comprises means for extracting an alternating signal from the antenna circuit, and in which the interface circuit uses the alternating signal extracted from the antenna circuit as emulation signal.

According to one embodiment, the NFC component comprises an active operating mode where the NFC component applies a triggering signal to the antenna circuit and a passive operating mode where the NFC component extracts the alternating signal from the antenna circuit.

According to one embodiment, the NFC component comprises a second connection terminal to connect one second antenna connection terminal to the host integrated circuit, and means to apply a direct voltage to the second antenna connection terminal, to electrically power the host integrated circuit.

According to one embodiment, the NFC component comprises a ground terminal to connect a ground terminal of the host integrated circuit to a ground circuit of the NFC component.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

In the drawings:

FIG. 1 previously described shows under block form a conventional architecture of NFC chipset;

FIG. 2 previously described shows various applications of a NFC chipset integrated in a mobile phone;

FIG. 3 previously described shows under block form the conventional architecture of a NFC component present un the NFC chipset of FIG. 1 and linked to a host integrated circuit;

FIGS. 4A-4B previously described show two conventional connection modes of a host integrated circuit to the NFC component of FIG. 3;

FIG. 5 shows a NFC component linked to a host integrated circuit according to the method of the invention;

FIGS. 6A-6B show two conventional architectures of contactless integrated circuits,

FIG. 7 shows an embodiment of the NFC component of FIG. 5 provided to receive one of the integrated circuits shown on FIGS. 6A-6B;

FIGS. 8A-8D show signals allowing ISO-A coded incoming data received by the NFC component of FIG. 7 to be transferred to the integrated circuit;

FIGS. 9A-9D show signals allowing ISO-B coded incoming data received by the NFC component of FIG. 7 to be transferred to the integrated circuit;

FIGS. 10A-10D show signals allowing ISO-A coded outgoing data sent by the integrated circuit to be transferred to the NFC component of FIG. 7;

FIGS. 11A-11D show signals allowing ISO-B coded outgoing data sent by the integrated circuit to be transferred to the NFC component of FIG. 7;

FIGS. 12A-12B show contactless integrated circuits according to FIGS. 6A, 6B connected to the NFC component of FIG. 7;

FIG. 13 shows an embodiment of the NFC component of FIG. 7;

FIG. 14 shows another embodiment of the NFC component of FIG. 7;

FIG. 15 shows another embodiment of the NFC component of FIG. 7; and

FIG. 16 shows the structure of an interface circuit according to the invention, present in the NFC component of FIG. 15.

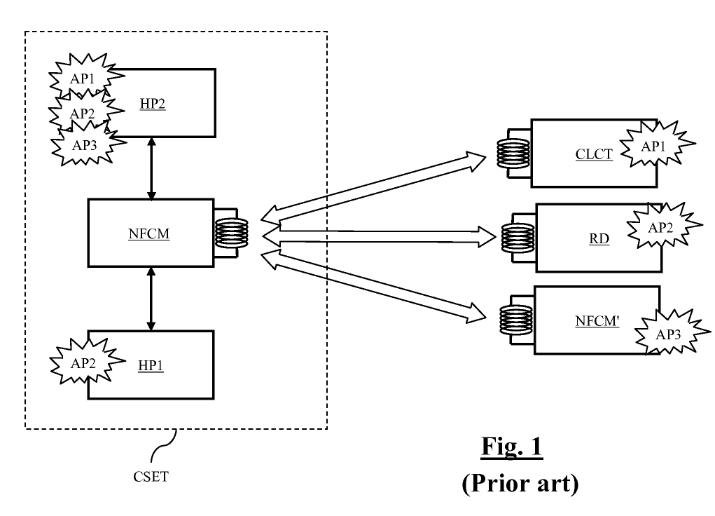

### DETAILED DESCRIPTION OF THE INVENTION

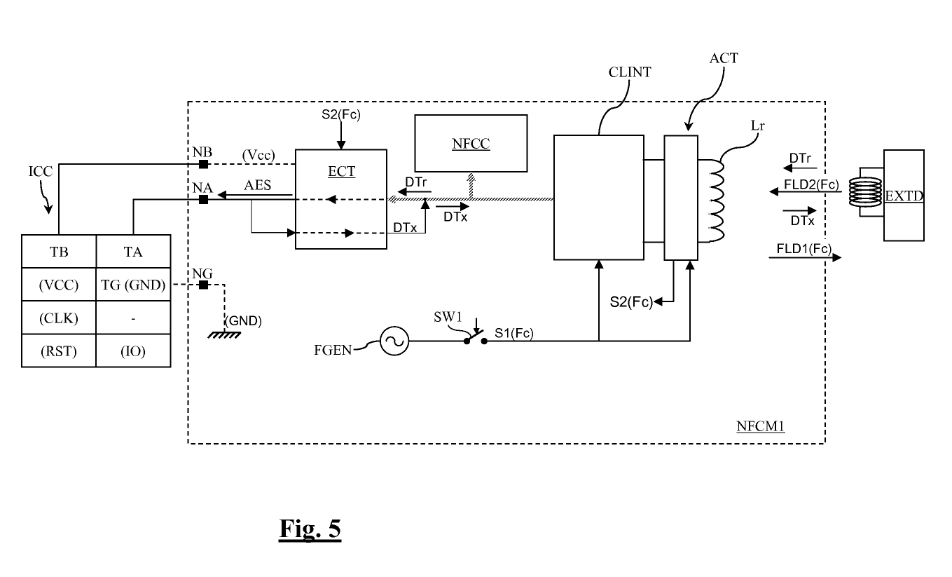

FIG. 5 schematically shows the structure of a NFC component designated “NFCM1”, comprising means for establishing a data path with a contactless integrated circuit ICC in accordance with the method of the invention, the integrated circuit ICC being connected to the component NFCM1 as host processor.

The component NFCM1 usually comprises a controller NFCC, an interface circuit CLINT and an antenna circuit ACT comprising an antenna coil Lr. The interface circuit CLINT is connected to the antenna circuit ACT and forms therewith the contactless communication interface of the component (or contactless data sending/receiving interface). When the component NFCM1 is in the active mode, a generator FGEN (oscillator for example) supplies to the antenna circuit ACT a signal S1 (Fc) of frequency Fc, as triggering signal, for emitting an alternating magnetic field FLD1 (Fc). A switch SW1 shown in the open state schematizes the fact that the triggering signal S1 (Fc) is no longer applied to the antenna circuit when the component NFCM1 is in the passive mode, the generator FGEN being preferably not powered. In the passive mode, the antenna circuit ACT is triggered by an external magnetic field FLD2 (Fc) emitted by an external device EXTD (RFID reader or NFC component in the active mode) and supplies an alternating signal S2 (Fc) from a voltage appearing by inductive coupling in the antenna coil Lr.

The integrated circuit ICC comprises two antenna terminals TA, TB (antenna connection pads) intended to be connected to an antenna coil. According to an embodiment of the present invention, the integrated circuit ICC has no antenna coil and is linked to the component NFCM1 by means of its antenna terminals TA, TB.

The component NFCM1 comprises an interface circuit ECT according to the invention, a first connection terminal NA linked to the interface circuit ECT and a second connection terminal NB. The terminal NA is linked to the first antenna terminal TA of the integrated circuit ICC to form a first wire link NA-TA. The terminal NB is optionally linked to the second antenna terminal TB of the integrated circuit, to form a second wire link NB-TB.

These so-called wire links can comprise an intermediate connector, not shown here, for example contact blades which lean on the antenna terminals TA, TB of the integrated circuit. In addition, the “antenna terminals” can be contact pads specifically provided for the implementation of the invention and electrically linked to the antenna connection pads TA, TB, the modification to be made to an integrated circuit to implement such additional contact pads being minor.

The integrated circuit ICC can be of the hybrid (or “combi”) type described by European Patent No. EP 0 917 684 in the name of the applicant, and also comprise ISO 7816 contacts (VCC, GND, CLK, RST, IO), as shown in FIG. 5. However, those are not used here because of the aforementioned drawbacks of the ISO 7816 bus.

Thus, according to an embodiment of the invention, the component NFCM1 is electrically linked to the integrated circuit ICC instead of an antenna coil. The ground contact GND of the integrated circuit can optionally be connected to a ground terminal NG of the component NFCM1 in order to counterbalance the respective ground potentials of the component NFCM1 and of the integrated circuit ICC. If the integrated circuit is not hybrid, a specific ground contact TG can be provided to that effect. However, as it will be seen hereinafter, the connection of the respective grounds of the component NFCM1 and the integrated circuit ICC is not essential to the implementation of the invention, the respective ground potentials naturally counterbalancing through the circuits of each element.

According to the invention still, the interface circuit ECT applies at least to the first antenna terminal TA an alternating signal AES which emulates the antenna signal that the integrated circuit ICC would receive if it was equipped with its antenna coil and if the antenna coil was plunged in an alternating magnetic field.

The emulation signal AES oscillates at a frequency Fc which is that of the working frequency or tuning frequency of the antenna circuit (not used) of the integrated circuit ICC, which is usually identical to the working frequency of the antenna circuit ACT of the component NFCM1. In that case, the signal S2 (Fc) supplied by the antenna circuit ACT is used as emulation signal AES and is supplied to the circuit ECT so that it applies it to the antenna terminal TA. The frequency Fc is for example about 13.56 MHz, as recommended by the ISO-A and ISO-B standards.

According to another aspect of the invention, the emulation signal AES is used to transmit to the integrated circuit ICC incoming data DTr supplied by the component NFCM1, or to transmit to the component NFCM1 outgoing data DTx supplied by the integrated circuit. The incoming data DTr are for example data received by the component NFCM1 in the passive mode by means of the antenna circuit ACT, during a communication with the external device EXTD. The data DTr are then injected by the interface circuit ECT in the emulation signal AES, so that the integrated circuit ACC receives them. The outgoing data DTx are for example data that must be sent by the integrated circuit ICC to the external device EXTD during the same communication. The data DTx are injected in the signal AES by the integrated circuit and are extracted by the interface circuit ECT to be sent to the external device EXTD by the component NFCM1.

According to an optional but advantageous feature of the invention, the antenna terminal TB of the integrated circuit ICC is used to supply thereto an electrical energy, for example under the form of a direct supply voltage Vcc which is applied by the circuit ECT to the antenna terminal TB via the connection terminal NB.

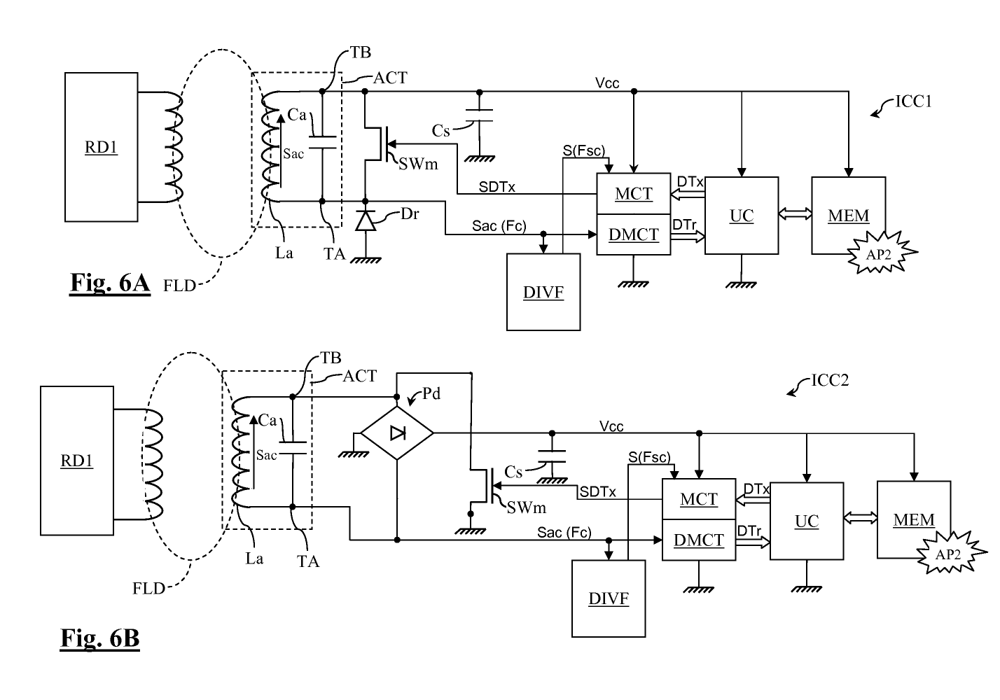

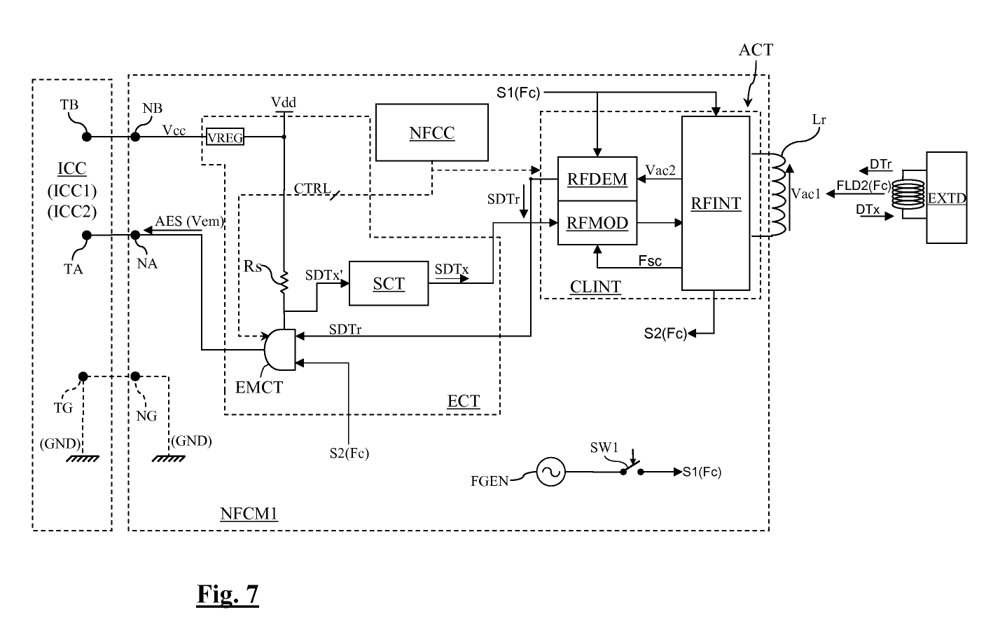

FIG. 7 shows an embodiment of the component NFCM1 provided to be compatible with two conventional architectures of contactless integrated circuits ICC1, ICC2 shown in FIGS. 6A and 6B. These two architectures are often found in the current production and will be firstly described, before reporting to FIG. 7.

Architectures of Contactless Integrated Circuits

The integrated circuits ICC1, ICC2 shown in FIGS. 6A-6B are of passive type powered by inductive coupling. Each comprises an antenna circuit comprising an antenna coil La and a tuning capacitor Ca in parallel. The capacitor Ca is usually integrated in the semi-conductor substrate of the integrated circuits whereas the antenna coil La is an external element connected to the antenna terminals TA, TB of each integrated circuit. In presence of an alternating magnetic field FLD emitted by a reader RD1, an alternating antenna signal Sac of frequency Fc appears in the antenna circuit.

Each integrated circuit also comprises a retromodulation switch SWm, for example a switch transistor of MOS type, a modulation circuit MCT, a demodulation circuit DMCT, a central unit UC (cabled-logic sequencer or microprocessor) and a memory MEM.

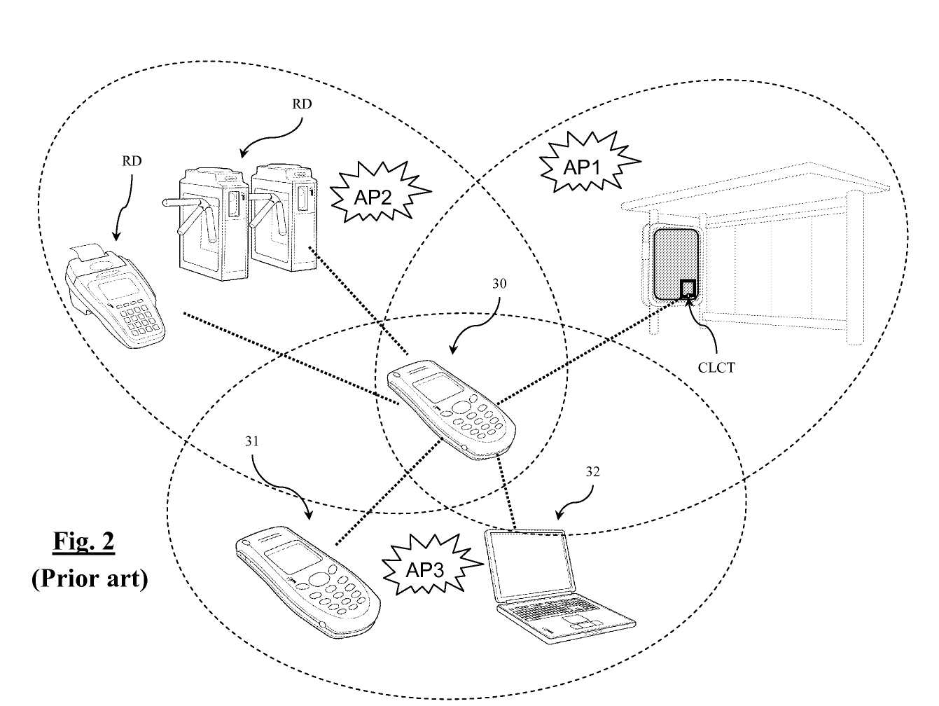

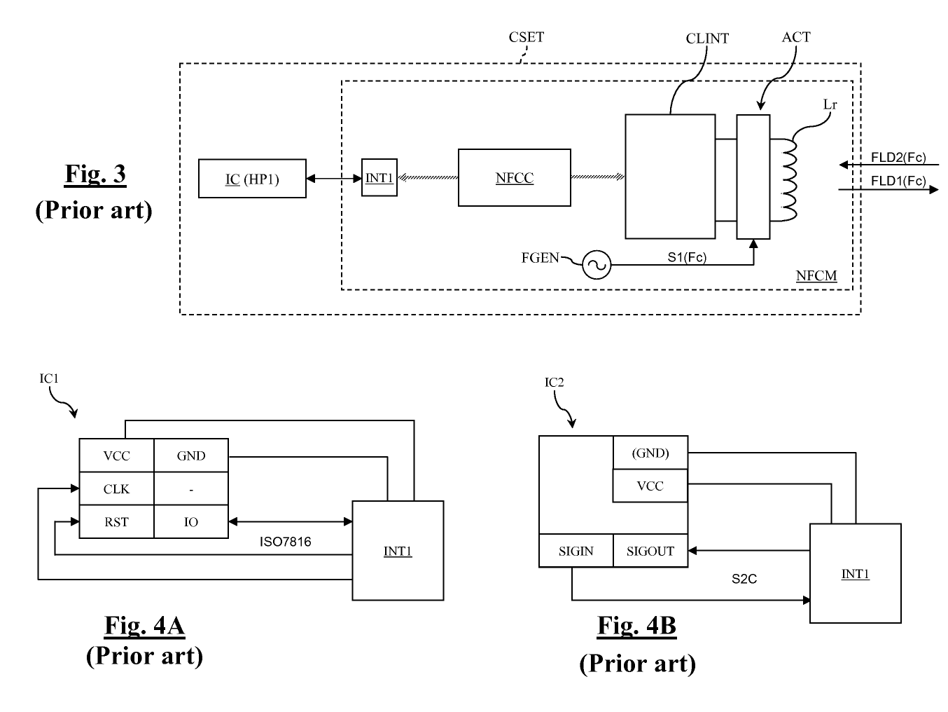

The memory MEM contains one or more application programs, in particular a program to manage an application of AP2 type (FIG. 2), and receives application data. The central unit UC supplies outgoing data DTx to the circuit MCT which applies to a control terminal of the switch SWm, for example the gate of the MOS transistor, a data DTx carrier signal SDTx. The switch SWm is connected to the antenna terminals TA, TB and its closing (passing state) triggers a partial short-circuit at the terminals of the antenna circuit (short-circuit with serial resistance, for example the intrinsic resistance of the MOS transistor) triggering the apparition of a retromodulation or charge modulation signal in the antenna circuit, at the rhythm of the data carrier signal SDTx. According to the standards ISO-A and ISO-B, the signal SDTx is modulated by a sub-carrier signal S (Fsc) oscillating at a frequency Fsc lower than a frequency Fc of the antenna signal Sac. The signal S (Fsc) is supplied to the circuit MCT by a frequency divider DIVF receiving the antenna signal Sac.

The integrated circuit ICC1 differs from the integrated circuit ICC2 in that it comprises a diode Dr for the half-wave rectification of the antenna signal Sac, whereas the integrated circuit ICC2 comprises a diode bridge Pd for the full-wave rectification of the antenna signal Sac.

In the integrated circuit ICC1, the diode Dr is reverse connected between the antenna terminal TA and the ground of the integrated circuit. A supply voltage Vcc appears on the terminal TB, by half-wave rectification, and is smoothed by a capacitor Cs connected between the terminal TB and the ground of the integrated circuit.

In the integrated circuit ICC2, the diode bridge Pd comprises a first terminal connected to the antenna terminal TB, a second terminal connected to the antenna terminal TA, a third terminal connected to the ground of the integrated circuit ICC2 and a fourth terminal connected to a smoothing capacitor Cs and supplying the supply voltage Vcc of the integrated circuit.

In each integrated circuit ICC1, ICC2, the antenna signal Sac is present on the antenna terminal TA which is thus electrically linked to the demodulation circuit DMCT for extracting the incoming data DTr, which are then supplied to the central unit UC.

Main Aspects of the Method According to the Invention

To create a data path with one of the contactless integrated circuits ICC1, ICC2 which has just been described, the method according to the invention consists of five main aspects:

(1) not connecting the antenna coil La;

(2) applying the alternating emulation signal AES to the antenna terminal TA, to emulate the antenna signal Sac;

(3) applying an external supply voltage Vcc to the antenna terminal TB, to replace the voltage Vcc extracted from the antenna signal Sac;

(4) injecting the data DTr in the emulation signal AES in a way adapted to the demodulation technique used by the demodulation circuit DMCT, so that it can extract them from the emulation signal and supply them to the central unit UC; and

(5) extracting the data DTx from the emulation signal AES in a way adapted to the retromodulation technique SDTx used by the modulation circuit MCT.

As indicated above, the aspect (3) remains optional and only concerns a passive integrated circuit which extracts its supply voltage Vcc from the antenna signal. In addition, the passive contactless integrated circuits could be equipped, at lower cost, with a specific supply terminal in order to receive a supply voltage through this terminal, instead of implementing this aspect of the invention, and that without being detrimental to the implementation of the other aspects of the invention.

Detailed Embodiment of the Component NFCM1

The component NFCM1 shown in FIG. 7 is connected to the antenna terminals TA, TB of an integrated circuit ICC which can be of the half-wave (ICC1) or full-wave (ICC2) rectification type. The component NFCM1 is in addition designed to implement the aspects (4) and (5) of the method of the invention in the case where the data are coded in accordance with the standards ISO-A or ISO-B. In other words, the data DTr are injected in the emulation signal AES according to the recommendations of the ISO-A standard or that of the ISO-B standard. Likewise, the data DTx are extracted from the signal AES according to the recommendations of one or the other standard.

The configuration ISO-A or ISO-B of the component NFCM1 can be determined in factory or be determined by the user, according to the type of integrated circuit ICC that is inserted in the component NFCM1 as host processor. However, as various contactless integrated circuits are compliant with ISO-A and ISO-B, the configuration ISO-A or ISO-B of the component NFCM1 can also be determined in a dynamic way by the controller NFCC according to the protocol in which a communication with the external device EXTD is established.

Structure of the Contactless Interface Circuit CLINT

The contactless interface circuit CLINT as shown in FIG. 7 conventionally comprises a demodulation circuit RFDEM and a modulation circuit RFMOD linked to the antenna circuit ACT. The latter comprises a stage RFINT connected to the antenna coil Lr. The stage RFINT comprises various conventional elements of antenna circuit as well as switches allowing the antenna circuit in active mode or in passive mode to be controlled, in particular retromodulation (passive mode) or active modulation (active mode) switches. Likewise, the circuits RFDEM and RFMOD are, usually, dual circuits that do not operate in the same way in active mode and in passive mode.

In the active mode, the circuit RFMOD modulates the amplitude of the triggering signal S1 (Fc) supplied by the generator FGEN. In the passive mode, the circuit RFMOD receives the data carrier signal SDTx (outgoing data) and applies a corresponding retromodulation signal to the antenna circuit ACT.

In the active mode, the circuit RFDEM detects and demodulates a retromodulation signal present in the antenna circuit ACT. In the passive mode, the circuit RFDEM demodulates an antenna signal Vac1 induced in the coil Lr by the magnetic field FLD2 (Fc) generated by the external device EXTD, and supplies a data carrier signal SDTr (incoming data). More particularly, the circuit RFDEM demodulates an electrical signal Vac2 which is supplied by the stage RFINT and which is the image of the induced signal Vac1.

The component NFCM1 will be hereinafter assumed to be in the passive mode when the host integrated circuit ICC performs the management of a contactless application, the component NFCM1 therefore becoming the “extension” of the integrated circuit for contactless data exchange, as it will clearly appear later.

Structure of the Interface Circuit ECT According to the Invention

The interface circuit ECT as shown in FIG. 7 comprises a modulation circuit EMCT and a data extraction circuit SCT. It directly receives the data carrier signal SDTr supplied by the demodulation circuit RFDEM and directly supplies to the modulation circuit RFMOD a data carrier signal SDTx extracted from the emulation signal AES. Thus, the data pass here in the component NFCM1 without being decoded.

Modulation Circuit EMCT

The modulation circuit EMCT receives the alternating signal S2 (Fc) supplied by the antenna circuit ACT (which is extracted from the antenna signal Vac1 by the stage RFINT) as well as the data carrier signal SDTr, and supplies the emulation signal AES to the antenna terminal TA of the integrated circuit ICC.

The modulation circuit EMCT injects the data DTr contained in the signal SDTr by modulating the amplitude of the signal AES by means of the signal SDTr (the data not being decoded, in this embodiment, as indicated above). When the signal SDTr has an inactive value, for example 0, meaning that no data is to be transmitted to the integrated circuit ICC, the signal AES is not modulated.

The amplitude modulation is performed according to the protocol ISO-A or ISO-B according to control signals supplied by the controller NFCC through a control bus CTRL (schematically shown in dotted line). The modulation circuit EMCT is here schematically shown under the form of an AND gate to illustrate the modulation function it implements. In practice, a simple AND gate is not sufficient to implement a 10% amplitude modulation (modulation factor) as recommended by the ISO-B standard, but is sufficient to implement a 100% amplitude modulation as recommended by the ISO-A standard.

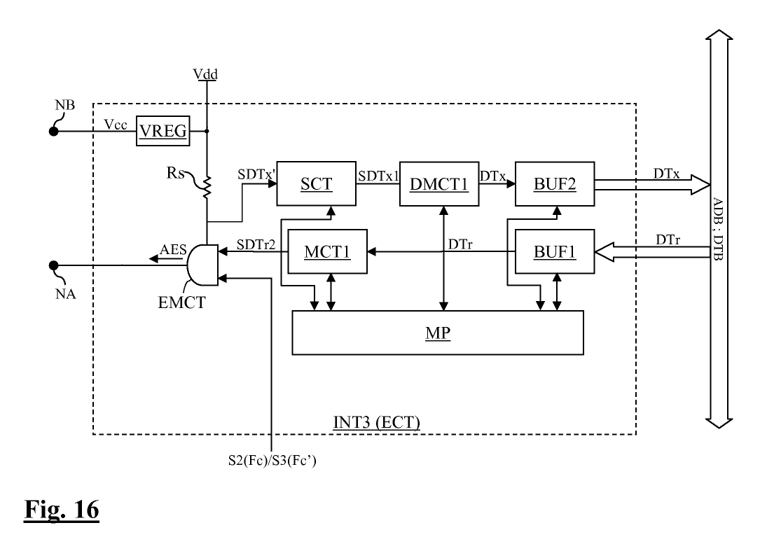

Some embodiments of an ISO-A and ISO-B compatible modulation circuit are described by European Patent Nos. EP 1 163 718 and EP 1 163 734 in the name of the applicant, which teaching is integrated here by reference. These patents describe a method for modulating the amplitude of an alternating logic signal with a variable amplitude modulation factor, particularly 100% and 10%, using microprocessor ports with a serial resistance not equal to zero. Here, the ports can be ports of the controller NFCC or ports of a specific controller integrated in the interface circuit ECT (Cf. microprocessor MP, embodiment shown in FIG. 16), or switchable resistors arranged in parallel, as it is also indicated by the aforementioned patents.

It will be however noted that the respect of the ISO-B standard at the level of the emulation signal AES is not imperative since the emulation signal is an internal signal. The amplitude modulation factor of the signal AES can therefore be determined with a higher degree of liberty, taking into account the electrical features of the integrated circuit ICC. For example, an amplitude modulation of the signal AES with a factor of 20% or even 5% could result preferable to a 10% modulation.

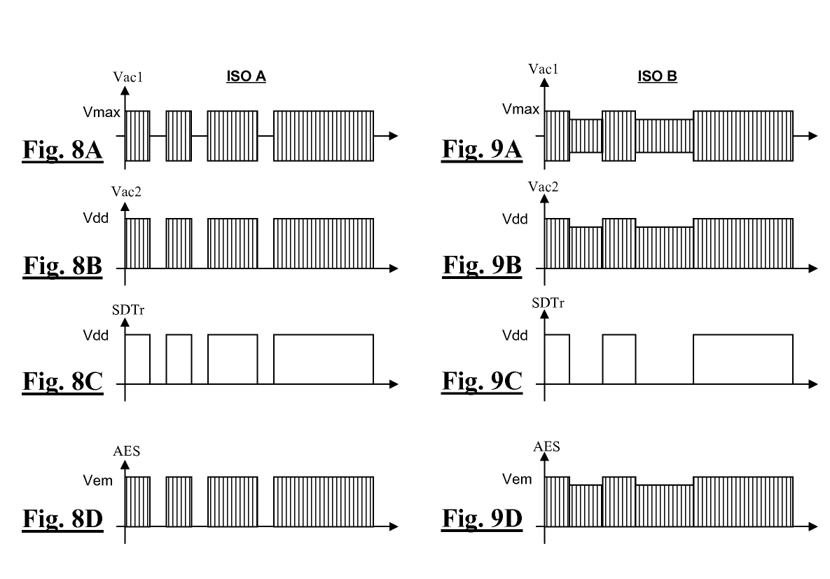

The operation of the circuit EMCT will be better understood by referring to FIGS. 8A to 8D and 9A to 9D, FIGS. 8A, 8B, 8C, 8D respectively show:

the antenna signal Vac1 when incoming data DTr are received according to the protocol ISO-A;

the signal Vac2, image of Vac1;

the incoming data carrier signal SDTr1; and

the emulation signal AES.

FIGS. 9A, 9B, 9C, 9D respectively show the same signals when incoming data DTr are received according to the protocol ISO-B.

In FIG. 8A, the data DTr are received according to a coding called “Modified Miller” and with a 100% amplitude modulation of the antenna signal Vac1. The peak voltage Vmax of the signal Vac1 can usually reach 12-16V according to the communication distance (distance between the component NFCM1 and the external device EXTD). In FIG. 9A, the data DTr are received according to a NRZ coding (“Non Return to Zero”) and a 10% modulation of the antenna signal Vac1, the peak voltage of the antenna signal being identical.

In FIGS. 8B and 9B, the signal Vac2 is the image of the signal Vac1 but only has positive alternations. Its maximum amplitude is brought to the value of a supply voltage Vdd of the component NFCM1.

In FIGS. 8C or 9C, the data carrier signal SDTr supplied by the demodulation circuit RFDEM is identical to the envelope of the signal Vac2, the carrier Fc having been suppressed by the circuit RFDEM.

In FIGS. 8D or 9D, the shape of the signal AES is identical to that of the signal Vac2. In effect the signal AES is here the result of the mixture of the demodulated signal SDTr and the signal S2 (Fc) which is here of the same frequency Fc as the signal Vac2. In other words, the transformation of the signal Vac2 in demodulated signal SDTr is temporary and the signal Vac2 is reconstituted by the circuit EMCT on the antenna terminal TA of the host integrated circuit ICC. The latter can thus demodulate the signal AES to find the signal SDTr, and extract the incoming data DTr it contains, after a step of modified Miller decoding or NRZ decoding performed by the central unit UC (FIGS. 6A-6B).

It will be noted on the contrary that the peak value Vem of the emulation signal is determined by the circuit EMCT and is preferably lower than the voltage Vdd, to limit the electrical consumption of the circuit EMCT. Some hundreds of millivolts are sufficient in practice for the emulation signal AES to be detected by the integrated circuit.

Extractor Circuit SCT

In FIG. 7, the data extraction circuit SCT extracts from the emulation signal AES the data carrier signal SDTx that the integrated circuit applies to the signal AES as retromodulation signal. The circuit SCT is for example a voltage sensor circuit which detects the variations of the current consumed by the circuit EMCT. To that effect, a variation signal SDTx′ is for example taken from the supply terminal of the circuit EMCT, and more precisely on the cathode of a resistor Rs through which the circuit EMCT receives the supply voltage Vdd of the component NFCM1. The signal SDTx′ is applied to the circuit SCT and is then put into shape as a logic signal forming the signal SDTx, to be sent to the modulation circuit RFMOD. Thus, when the integrated circuit ICC applies the modulation signal SDTx to its switch SWm (FIGS. 6A or 6B), the resistive short-circuit caused by the switch SWm openings and closings modifies the load impedance seen by the circuit EMCT and modifies the current consumed by the same, therefore making the signal SDTx′ vary.

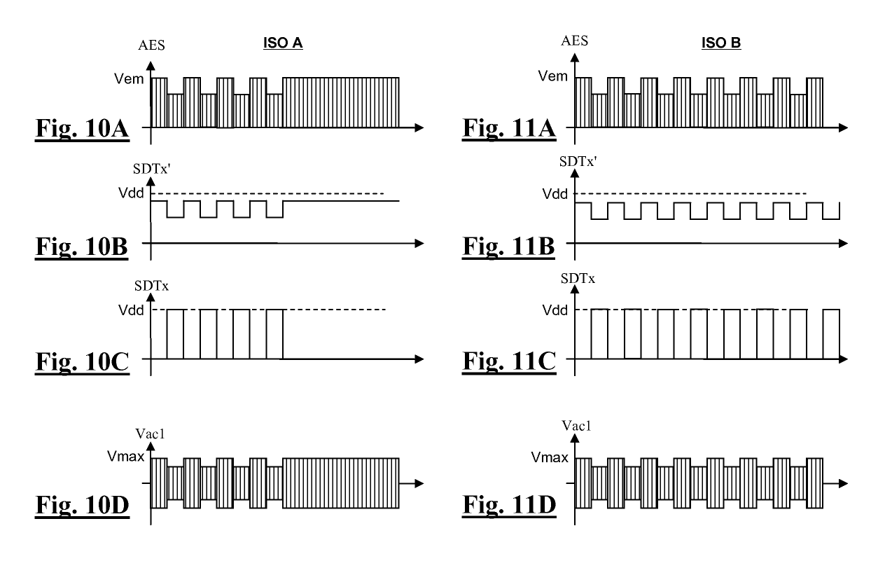

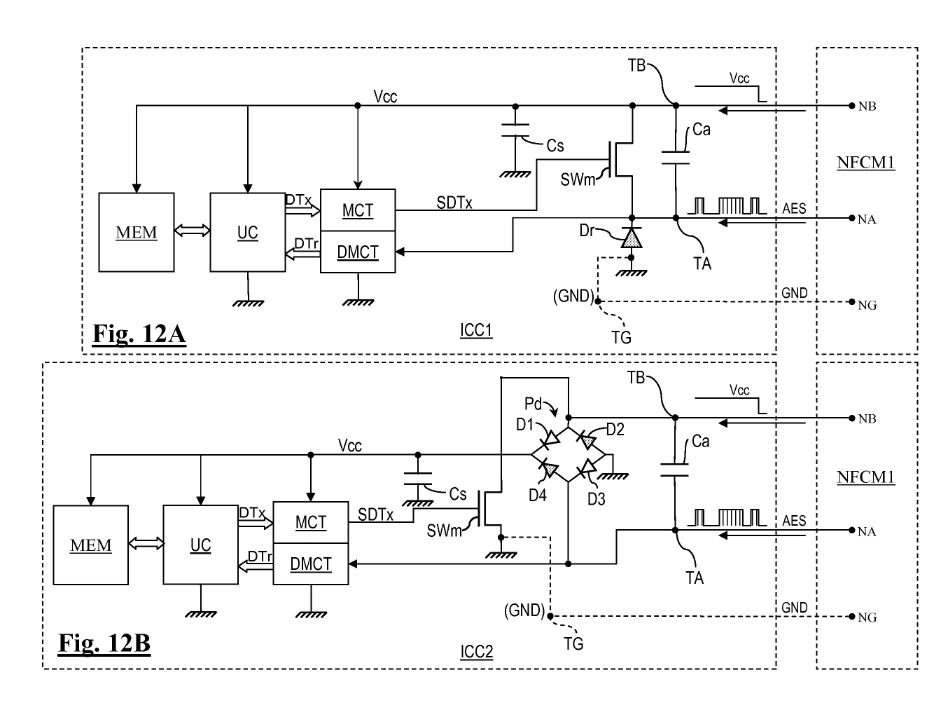

The operation of the extraction circuit SCT will be better understood by referring to FIGS. 10A to 10D and 11A to 11D. FIGS. 10A, 10B, 10C, 10D respectively show:

the shape of the signal AES when outgoing data DTx are sent by the integrated circuit ICC according to the ISO-A protocol;

the signal SDTx′ taken from the supply terminal of the circuit EMCT;

the signal SDTx supplied by the circuit SCT; and

the antenna signal Vac1 appearing in the antenna circuit ACT after applying the signal SDTx to the modulation circuit RFMOD of the interface circuit CLINT.

FIGS. 11A, 11B, 11C, 11D respectively show the same signals when outgoing data DTx are emitted by the integrated circuit ICC according to the ISO-B protocol.

In FIG. 10A, the signal AES being modulated in amplitude by the sub-carrier signal Fsc described above carries the outgoing data DTx, a “1” being coded by an alternation Fsc/0 (modulation with the sub-carrier/no modulation) and a “0” being coded by a reverse alternation 0/Fsc (no modulation/modulation with the sub-carrier) or inversely. One data bit only is shown in FIG. 10A, for the sake of simplicity.

In FIG. 11A, the signal AES permanently being modulated in amplitude by the sub-carrier signal Fsc carries the outgoing data DTx, the transitions between a “1” and a “0” being marked by phase shifts or absences of phase shifts (PSK modulation or “Phase Shift Keying”). One data bit only is also shown in FIG. 10A for the sake of simplicity.

In FIGS. 10B and 11B, the signal SDTx′ varies with the amplitude modulation of the signal AES, for the reasons explained above.

In FIGS. 10C, 11C, the signal SDTx is the image of the signal SDTx′ but is put in shape by the circuit SCT to have net logic states, i.e., 1 (Vdd) and 0 (ground), whereas the signal SDTx′ varies between two voltage levels comprised between 0 and Vdd.

In FIGS. 10D, 11D, the antenna signal induced by the magnetic field FLD2 is modulated by the circuit RFMOD in accordance with the signal SDTx, and thus has variations of the amplitude of its envelope copying out the shape of the signal SDTx, i.e., in FIG. 10D periods of envelope variation at the rhythm of the sub-carrier Fsc followed by no envelope variation and in FIG. 11D a permanent envelope variation at the rhythm of the sub-carrier Fsc having phase shifts.

Thus, the antenna signal Vac1 reproduces the modulations of the emulation signal AES and is modulated as if the host integrated circuit ICC directly controlled the antenna circuit ACT by means of its own modulation circuit MCT, without passing through the interface circuit ECT according to the invention and without using the modulation circuit RFMOD of the interface circuit CLINT.

Aspect of the Invention Relating to the Electrical Supply of the Host Integrated Circuit

FIG. 7 also shows the implementation of the aspect (3) of the method of the invention. The component NFCM1 here comprises a voltage regulation circuit VREG powered by the voltage Vdd, which output supplies to the antenna terminal TB of the integrated circuit ICC, via the connection terminal NB of the component NFCM1, a supply voltage Vcc adapted to the integrated circuit. The voltage Vcc is for example of 1.5V or 3V and the voltage Vdd is for example of 3V or 5V.

The compatibility of this aspect of the invention with the integrated circuits ICC1, ICC2 of FIGS. 6A and 6B can be checked by referring to FIGS. 12A, 12B which respectively show the integrated circuits ICC1 and ICC2 connected to the component NFCM1 of FIG. 7 (here shown under the form of a block).

In FIG. 12A, it appears that the voltage Vcc supplied by the component NFCM1 directly goes into the feeder of the integrated circuit ICC1. In addition, the diode Dr is reverse biased and is not an obstacle to the application of the signal AES to the input of the demodulation circuit DMCT of the integrated circuit ICC1. Tests and simulations have shown that the respective ground potentials of the component NFCM1 and the integrated circuit ICC1 counterbalance each other through the circuitry of the integrated circuit (central unit UC, circuits MCT, DMCT, memory MEM, etc.). Thus, the connection of the ground terminal NG of the component NFCM1 and the ground contact TG of the integrated circuit ICC1 is not essential, although it can improve the performances of the integrated circuit in some cases, according to the structure and the manufacturing technology of the integrated circuit ICC1.

In FIG. 12B, it also appears that the voltage Vcc supplied by the component NFCM1 goes into the feeder of the integrated circuit ICC2 through a diode D1 of the diode bridge Pd, which is conducting. In addition, diodes D2 and D4 of the diode bridge are reverse biased and do not prevent the application of the signal AES to the input of the demodulation circuit DMCT of the integrated circuit ICC2. Tests and simulations have also shown that the respective ground potentials of the component NFCM1 and the integrated circuit ICC1 counterbalance each other through the circuitry of the integrated circuit and that a diode D3 of the diode bridge contributes to this balance. Thus, as previously described, the connection of the ground terminal NG of the component NFCM1 and the ground contact of the integrated circuit ICC2 is not essential, although it can improve the performances of the integrated circuit in some cases.

Embodiments of the NFC Component According to the Invention

The component NFCM1 as shown in FIG. 7 is an elementary embodiment only used to expose the basic principles of the method according to the invention. Thus, in this embodiment, the component NFCM1 is completely transparent in relation to the incoming and outgoing data flow and no means for linking the interface circuit CLINT to another host processor is shown, nor any means for communicating between the host integrated circuit ICC and the controller NFCC. Now, in relation with FIGS. 14 to 16, embodiments of the NFC component according to the invention will be described, which offer all or part of these advantages, as well as other advantages that will appear later.

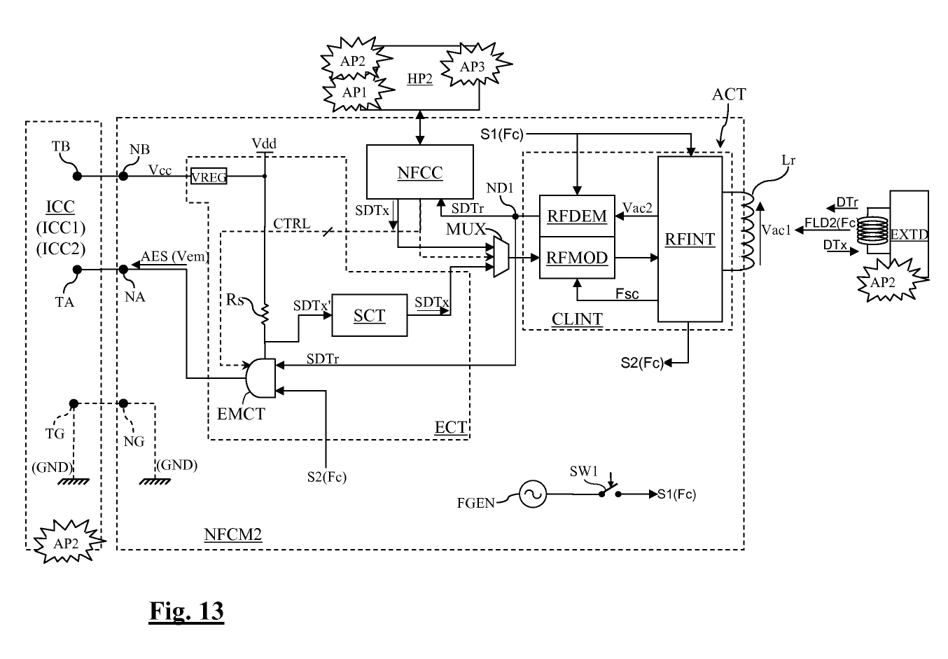

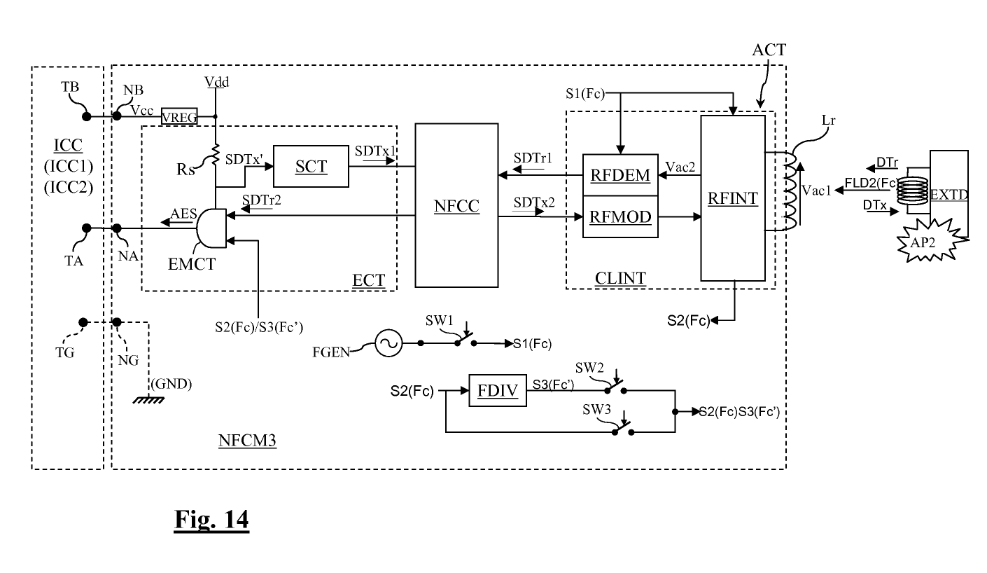

### Embodiment 1, FIG. 13

In FIG. 13, the NFC component, designated “NFCM2”, is provided to receive another host processor HP2. It allows a communication to be established between, on the one hand the external device EXTD and on the other hand, the host integrated circuit ICC or the host processor HP2.

Performing the application concerned, for example an application of AP2 type, can for example be entrusted to the integrated circuit ICC if it is secure and if the application is not free or requires access conditions to secure (subscription for example). Performing the application can also be entrusted to the processor HP2 if it is not secure and if the application is free and without secure access condition. The processor HP2 can also be used to manage applications of AP1 or AP3 type (FIG. 2).

To that end, the outgoing data DTx carrier signal SDTx as applied to the circuit RFMOD can be supplied by the processor HP2, for example via the controller NFCC, or by the integrated circuit ICC, via the interface circuit ECT. In order to avoid short-circuits between electric potentials, a multiplexer MUX links the input of the circuit RFMOD both to the controller NFCC and to the interface circuit ECT and performs the routing of the signal SDTx. The multiplexer MUX is driven by the controller NFCC by means of the control bus CTRL.

Likewise, the incoming data DTr carrier signal SDTr supplied by the circuit RFDEM is applied to both the controller NFCC and the interface circuit ECT, by means of a derivation node ND1, which allows data DTr to be routed toward the host processor HP2 or toward the integrated circuit ICC. In the first case the circuit ECT is deactivated by the controller NFCC, by means of the control bus CTRL, and the data carrier signal SDTr is processed by the controller NFCC or directly sent to the host processor HP2. In the second case the circuit ECT is activated and the signal SDTr is not processed by the controller NFCC.

### Embodiment 2, FIG. 14

In FIG. 14 the NFC component, designated “NFCM3”, differs from the component NFCM1 in that the NFC controller is interposed in the incoming and outgoing data flow. The incoming data carrier signal supplied by the demodulation circuit RFDEM to the controller NFCC is designated SDTr1 whereas the incoming data carrier signal supplied by the controller NFCC to the interface circuit ECT is designated SDTr2. Likewise, the outgoing data carrier signal supplied by the interface circuit ECT to the controller NFCC is designated SDTx1 and the outgoing data carrier signal supplied by the controller NFCC to the modulation circuit RFMOD is designated SDTx2.

The signal SDTr1 can be processed or not by the controller NFCC. If the controller NFCC sends the signal SDTr1 back to the interface circuit ECT as it is (SDTr2=SDTr1), the operating mode obtained is therefore identical to that of FIG. 7 (component NFCM3 transparent to the host integrated circuit). The controller NFCC can also process this signal by decoding it, and regenerate it with another encryption. In this case, the controller NFCC allows the communication protocol to be converted. For example, the antenna circuit ACT receives data in ISO-A mode and the processor sends them to the interface circuit ECT in ISO-B mode, or vice-versa. The controller NFCC can also transfer the signal SDTr1 to another host processor HP2 (not shown here, cf. FIG. 13). Eventually, the controller NFCC can also generate the signal SDTr2 from data it wishes to send to the host integrated circuit, without its receiving the signal SDTr1. In that case, an internal communication is established between the controller NFCC and the host integrated circuit, without communication with the external world.

Similar processing possibilities are offered by the component NFCM3 insofar as the outgoing data carrier signal is concerned. The signal SDTx1 can be processed or not by the controller NFCC. If the controller NFCC sends the signal SDTx1 back to the modulation circuit RFMOD as it is (SDTx2=SDTx1), the operating mode obtained is identical to that of FIG. 7. If the controller NFCC processes this signal by decoding it and regenerating it with another encryption, the controller NFCC therefore performs a conversion of the communication protocol. The controller NFCC can also receive an outgoing data carrier signal emitted by another host processor HP2 (not shown here, cf. FIG. 13) and apply it to the interface circuit RFINT. The controller NFCC can also generate the signal SDTx2 from data it wishes to send to an external device EXTD, without receiving the signal SDTx1. In that case, an external communication is established between the controller NFCC and the external device EXTD, without the participation of the host integrated circuit ICC.

Besides a protocol conversion, embodiments of the invention also allow the working frequency of the component NFCM3 to be converted in relation to the working frequency of the host integrated circuit ICC. To that end, the modulation circuit EMCT of the interface circuit ECT receives a signal S3 (Fc′) having a frequency Fc′ different from the working frequency Fc of the antenna circuit ACT of the component NFCM3. As schematically shown in FIG. 14, a frequency divider FDIV receiving the signal S2 (Fc) supplies the signal S3 (Fc′). Switches SW2, SW3 driven by the controller NFCC allow one or the other signal to be applied to the modulation circuit EMCT.

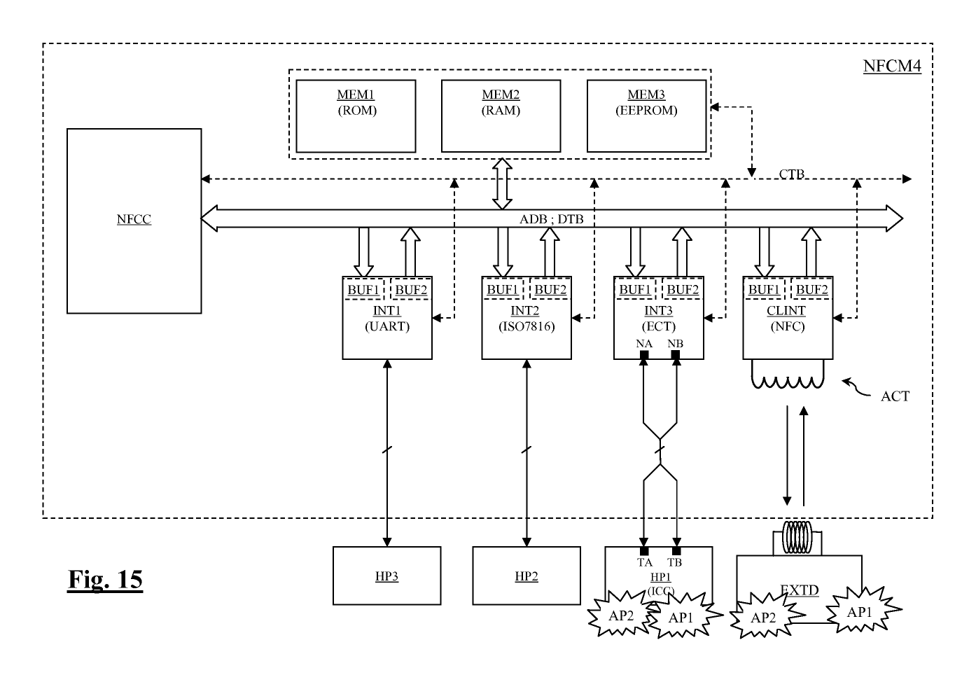

### Embodiment 3, FIGS. 15 and 16

The embodiment shown in FIG. 15 of the NFC component according to the invention, designated “NFCM4”, forms an entity of computational type in which data circulate on a data bus DTB associated to an address bus ADB, the data and address buses being controlled by the controller NFCC. In this embodiment, the interface circuit ECT according to the invention is a peripheral element of the controller NFCC.

The Component NFCM4 More Particularly Comprises:

the controller NFCC and the interface circuit CLINT already described;

a memory array comprising for example a program memory MEM1 (ROM memory), a volatile data memory MEM2 (RAM) and an electrically erasable and programmable data memory MEM3 (EEPROM);

a communication port INT1 of UART type, to which a host processor HP3 can be connected;

a communication port INT2 of ISO 7816 type to which a host processor HP2 can be connected (for example a SIM card);

a connection port INT3/ECT according to the invention allowing the integrated circuit ICC to be connected;

the aforementioned data bus DTB and address bus ADB, linking the memory array, the controller NFCC, the interface circuit CLINT and the ports INT1, INT2, INT3; and

a control bus CTB allowing these various elements to be controlled and read and/or write accessed by the controller NFCC.

The interface CLINT and the ports INT1, INT2, INT3 comprise each an input buffer BUF1 at parallel input and an output buffer BUF2 at parallel output respectively accessible in writing and in reading, via the data bus and the address bus. The exchange of data forming routing commands or data frames between the host processors HP1, HP2, HP3, the interface circuit CLINT and the controller NFCC is thus performed by data blocks the size of buffers BUF1, BUF2.

An embodiment of the interface circuit INT3/ECT is shown in FIG. 15. The circuit INT3/ECT comprises a microprocessor MP, a modulation circuit MCT1 and a demodulation circuit DMCT1 in addition to the elements EMCT, SCT, BUF1, BUF1 already described. The modulation circuit MCT1 has an input linked to the output of the buffer BUF1 and an output linked to the input of the modulation circuit EMCT. This output supplies the incoming data carrier signal SDTr2 from incoming data DTr present in the buffer BUF1, received via the data bus DTB. The demodulation circuit DMCT has an input linked to the output of the circuit SCT and an output linked to an input of the buffer BUF2. The input of the circuit DMCT receives the outgoing data carrier signal SDTx1 and the output of this circuit supplies to the buffer BUF2 decoded data DTx, so that they are sent to the data bus. The microprocessor MP controls the circuits MCT1 and DMCT1 and can deactivate them if the incoming data DTr are already received coded under the form of signal SDTr and if the signal SDTx must be sent on the bus without decoding. The microprocessor MP receives commands of the controller NFCC allowing the interface INT3/ECT to be configured as wished (coding/decoding mode, transparent mode).

In this embodiment, the circuit INT3/ECT is thus functionally independent of the controller NFCC insofar as data injection in the emulation signal and data extraction from the emulation signal are concerned. The data it receives or it sends can be coded under the form of data carrier signal, as described above (the signal being seen as data to be carried via the data bus) or not coded. In that case, the incoming data DTr received via the data bus are transformed in signal SDTr to be applied to the host integrated circuit ICC. Likewise, the signal SDTx extracted by the interface circuit INT3/ECT is decoded and sent on the bus under the form of data DTx, for the attention of the controller NFCC, which then generates the outgoing data carrier signal SDTx and applies it to the interface circuit CLINT via the data bus.

This embodiment thus has all the features of the other embodiments. The internal data flows can be coded or not, protocol changes can be provided or not. Data paths can be established between the external device EXTD and each host processor and internal data paths can be established between the controller NFCC and each host processor, etc.

This embodiment also allows the component NFCM4 to be configured in the active mode while the host integrated circuit ICC dialogs with the external device EXTD, which is then in passive mode. That makes it possible to give to a passive secure integrated circuit like the integrated circuit ICC the possibility to dialog with external devices also passive, for example to control applications of AP1 type (Cf. FIG. 2) in which the access to the information contained by the passive external device must be secured. The external device EXTD is for example a contactless chip card forming an electronic wallet that users wish to reload with monetary units by means of their mobile phones, after obtaining the authorization of their banks via the host processor HP3 (baseband), the operation of reloading the wallet being under the control of the host integrated circuit ICC.

It will clearly appear to those skilled in the art that the present invention is susceptible of various other embodiments, by combining all or part of the features implemented in each embodiment described above.

It will also clearly appear to those skilled in the art that embodiments of the present invention are not reserved to the integrated circuits RF operating by inductive coupling. The invention is applicable to other types of contactless integrated circuits, particularly contactless integrated circuits UHF operating by electrical coupling, provided to receive an antenna UHF and comprising retromodulation means arranged to modulate the impedance of the antenna UHF in order to modulate its refection factor. The communication interface of the NFC component can also be of the UHF type instead of being at inductive coupling. Globally, the invention allows an integrated circuit UHF or an integrated circuit RF to be integrated in a NFC component having an inductive coupling communication interface RF or an integrated circuit UHF or an integrated circuit RF to be integrated in a NFC component having an electrical coupling communication interface UHF.

It will be appreciated by those skilled in the art that changes could be made to the embodiments described above without departing from the broad inventive concept thereof. It is understood, therefore, that embodiments of the present invention are not limited to the particular embodiments disclosed, but it is intended to cover modifications within the spirit and scope of the present invention as defined by the appended claims.

I claim:

1. A method for exchanging data with an integrated circuit, the integrated circuit comprising antenna connection terminals and means for receiving and sending data from an antenna signal received on the antenna connection terminals, the method comprising:
not connecting the antenna connection terminals of the integrated circuit to an antenna;
applying an alternating emulation signal at least to one first antenna connection terminal of the integrated circuit, by means of a wire link, in order to emulate the presence of an antenna signal on the first antenna connection terminal;
sending data to the integrated circuit by injecting them in the emulation signal; and
receiving data sent by the integrated circuit by taking them from the emulation signal.

2. The method according to claim 1, wherein injecting data in the emulation signal comprises modulating the emulation signal by means of a data carrier signal.

3. The method according to claim 2, wherein the data present in the data carrier signal are obtained by demodulating an antenna signal received through an antenna circuit of a component hosting the integrated circuit.

4. The method according to claim 1, wherein taking data from the emulation signal comprises extracting a data carrier retromodulation signal by detecting current or voltage variations in the emulation signal.

5. The method according to claim 1, comprising applying a direct voltage to one second antenna connection terminal of the integrated circuit, to electrically power the integrated circuit.

6. The method according to claim 1, comprising linking a ground terminal of the integrated circuit to a ground terminal of a device used to exchange data with the integrated circuit.

7. A method for establishing a data path between a host integrated circuit and a NFC component comprising an antenna circuit for receiving and sending contactless data, the host integrated circuit comprising antenna connection terminals and means to receive and send data by demodulating an antenna signal received on the antenna connection terminals, the method comprising:
not connecting the antenna connection terminals of the host integrated circuit to an antenna;
linking at least one first antenna connection terminal of the host integrated circuit to the NFC component by means of a wire link;
applying an alternating emulation signal supplied by the NFC component at least to the first antenna connection terminal, in order to emulate the presence of an antenna signal;
injecting data supplied by the NFC component in the emulation signal; and
taking from the emulation signal data sent by the host integrated circuit and supplying them to the NFC component.

8. The method according to claim 7, wherein injecting data in the emulation signal comprises modulating the emulation signal by means of a data carrier signal.

9. The method according to claim 8, comprising producing the data carrier signal by demodulating an antenna signal received in the antenna circuit of the NFC component so that the data received by the NFC component are sent to the host integrated circuit in a transparent way.

10. The method according to claim 8, wherein injecting data in the emulation signal comprises:
demodulating an antenna signal received in the antenna circuit of the NFC component to produce a first data carrier signal;
decoding the first data carrier signal;
rebuilding a second data carrier signal from data present in the first data carrier signal; and
modulating the emulation signal, by means of a second data carrier signal.

11. The method according to claim 10, wherein the second data carrier signal has an encryption different from an encryption of the first data carrier signal.

12. The method according to claim 7, wherein taking data from the emulation signal comprises extracting a data carrier retromodulation signal, by detecting current or voltage variations in the emulation signal.

13. The method according to claim 12, comprising applying the retromodulation signal to a modulation circuit of the NFC component, so that the NFC component resends the data via the antenna circuit in a transparent way.

14. The method according to claim 7, wherein taking data from the emulation signal comprises:
extracting a first data carrier retromodulation signal from the emulation signal;
decoding the first retromodulation signal;
rebuilding a second retromodulation signal from data present in the first retromodulation signal; and
applying the second retromodulation signal to a modulation circuit to send data via the antenna circuit of the NFC component.

15. The method according to claim 14, wherein the second retromodulation signal has an encryption different from an encryption of the first outgoing data carrier signal.

16. The method according to claim 7, wherein the emulation signal oscillates at the same frequency as a working frequency of the antenna circuit of the NFC component.

17. The method according to claim 7, wherein the emulation signal oscillates at a frequency different from a working frequency of the antenna circuit of the NFC component.

18. The method according to claim 7, comprising extracting an alternating signal of the antenna circuit, and using the alternating signal as emulation signal.

19. The method according to claim 18, comprising configuring the NFC component so that the NFC component comprises an active operating mode where the NFC component applies a triggering signal to the antenna circuit and a passive operating mode where the NFC component extract the alternating signal from the antenna circuit.

20. The method according to claim 7, comprising:
linking one second antenna connection terminal to the NFC component by means of a wire link; and
applying a direct voltage to the second antenna connection terminal, to electrically power the host integrated circuit.

21. The method according to claim 7, comprising linking a ground terminal of the host integrated circuit to a ground terminal of the NFC component.

22. A NFC component provided for receiving at least one host integrated circuit in order to exchange data with the host integrated circuit, and comprising:
an antenna circuit for receiving and sending contactless data;
at least one connection terminal to connect an antenna connection terminal of a host integrated circuit of contactless operation type but without antenna; and
an interface circuit to:
apply an alternating emulation signal to the antenna connection terminal of the host integrated circuit, in order to emulate the presence of an antenna signal;
inject data supplied by the NFC component in the emulation signal; and
take data sent by the host integrated circuit from the emulation signal.

23. The NFC component according to claim 22, wherein the interface circuit is arranged for injecting data in the emulation signal by modulating the emulation signal by means of a data carrier signal.

24. The NFC component according to claim 23, comprising a demodulator to demodulate an antenna signal received in the antenna circuit and in which the data carrier signal is supplied to the interface circuit without processing so that the data received via the antenna circuit are sent to the host integrated circuit in a transparent way.

25. The NFC component according to claim 23, comprising:
a demodulator to demodulate an antenna signal received in the antenna circuit and supply a first data carrier signal to the interface circuit;
first processing means to rebuild a second data carrier signal from data present in the first data carrier signal; and
a modulation circuit to modulate the emulation signal by means of the second data carrier signal.

26. The NFC component according to claim 25, wherein the first processing means rebuild the second data carrier signal with an encryption different of an encryption of the first data carrier signal.

27. The NFC component according to claim 25, wherein the first processing means comprise a main controller of the NFC component.

28. The NFC component according to claim 25, wherein the first processing means comprise a dedicated modulation circuit of the interface circuit, different from a main controller of the NFC component.

29. The NFC component according to claim 22, wherein the interface circuit comprises a detection circuit to detect current or voltage variations in the emulation signal and extract from the emulation signal a data carrier retromodulation signal.

30. The NFC component according to claim 29, comprising a modulation circuit to send data via the antenna circuit, and in which the retromodulation signal is applied to the modulation circuit without processing so that the NFC component resends data via the antenna circuit in a transparent way.

31. The NFC component according to claim 29 comprising:
second processing means to rebuild a second retromodulation signal from data present in the first retromodulation signal; and
a modulation circuit to apply the second retromodulation signal to the antenna circuit and send data via the antenna circuit of the NFC component.

32. The NFC component according to claim 31, wherein the second processing means rebuild the second data carrier signal with an encryption different of an encryption of the first data carrier signal.

33. The NFC component according to claim 31, wherein the second processing means comprise a main controller of the NFC component.

34. The NFC component according to claim 31, wherein the second processing means comprise a dedicated demodulation circuit of the interface circuit, different from a main controller of the NFC component, to extract the data present in the first retromodulation signal.

35. The NFC component according to claim 22, wherein the emulation signal oscillates at the same frequency as a working frequency of the antenna circuit of the NFC component.

36. The NFC component according to claim 22, Wherein the emulation signal oscillates at a frequency different from a working frequency of the antenna circuit of the NFC component.

37. The NFC component according to claim 22, comprising means for extracting an alternating signal) from the antenna circuit, and in which the interface circuit uses the alternating signal) extracted from the antenna circuit as emulation signal.

38. The NFC component according to claim 37, comprising an active operating mode where the NFC component applies a triggering signal) to the antenna circuit and a passive operating mode where the NFC component extracts the alternating signal) from the antenna circuit.

39. The NFC component according to claim 22, comprising:
a second connection terminal to connect one second antenna connection terminal to the host integrated circuit; and
a control to apply a direct voltage to the second antenna connection terminal, to electrically power the host integrated circuit.

40. The NFC component according to claim 22, comprising a ground terminal to connect a ground terminal of the host integrated circuit to a ground circuit of the NFC component.
